(19) United States
(12) Patent Application Publication
(10) Pub. No.: US 2025/0014868 A1
(43) Pub. Date: Jan. 9, 2025

(54) ETCHING PLASMA PROCESSING APPARATUS INCLUDING CONSUMABLE METAL MEMBER

(71) Applicant: Research & Business Foundation SUNGKYUNKWAN UNIVERSITY, Suwon-si (KR)

(72) Inventors: Geun Young YEOM, Seoul (KR); Dong Woo KIM, Seoul (KR); Hye Joo LEE, Suwon-si (KR); Hyun Woo TAK, Yongin-si (KR); Myeong Ho PARK, Ansan-si (KR); Chan Hyuk CHOI, Yongin-si (KR); Jun Soo LEE, Uiwang-si (KR)

(73) Assignee: Research & Business Foundation SUNGKYUNKWAN UNIVERSITY, Suwon-si (KR)

(21) Appl. No.: 18/282,292

(22) PCT Filed: Mar. 23, 2023
(86) PCT No.: PCT/KR2023/003858

§ 371 Date: Sep. 15, 2023

(30) Foreign Application Priority Data
Mar. 24, 2020 (KR) 10-2022-0036416

(51) Int. Cl. H01J 37/32

(52) U.S. Cl. CPC H01J 37/32422; H01J 37/3244; H01J 37/32715; H01J 2237/334

(57) ABSTRACT

An etching plasma processing apparatus including a consumable metal member is disclosed. The etching plasma processing apparatus includes a vacuum chamber, a substrate support member arranged inside the chamber, a gas supply member for injecting gas into the chamber, a consumable part arranged inside the chamber and generating a metallic byproduct containing ions or radicals of a first metal when plasma is generated inside the chamber, a first electrode for applying power to generate plasma inside the chamber, a second electrode facing the first electrode, and a power supply supplying power to the first and second electrodes.

### TECHNICAL FIELD

The present invention relates to an etching plasma processing apparatus including a consumable metal member containing refractory metal as a constituent included in a specialty gas.

### BACKGROUND ART

The uneven polymer passivation on the sidewalls and the charging effect that hinders the vertical ion implantation were still problems that needed to be solved in the conventional high aspect ratio contact process, which is one of the semiconductor etching processes. To address the issues of uneven polymer passivation and charging effects, research is being conducted on the process of introducing specialty gases during etching, and the most representative specialty gas is tungsten hexafluoride (WF₆). During the etching process, the tungsten within the introduced specialty gas, WF₆, combines with the polymer on the sidewalls, enabling the formation of a thinner and more uniform metal-incorporated polymer protective layer compared to conventional carbon-based polymers. The metal-incorporated polymer protective layer, due to the robust properties of refractory metals, exhibits superior performance in sidewall protection compared to conventional carbon-based polymer single-component layers, helping improve the charging effect caused by positive ions and allowing for the achievement of vertical etching results. In addition, the combination of the metal contained within the specialty gas injected during the etching process and the amorphous carbon layer (ACL) can further enhance the etching selectivity of the ACL mask layer.

However, in the case of such specialty gas addition processes, additional gas line expansion is required for the introduction of specialty gases, and an additional step of supplying limited types of refractory metal bonding materials in gas form to the chamber is also necessary. Furthermore, the materials available for use as specialty gases are extremely limited, and even in the case of widely known WF₆ gas in conventional technology, there is a need to modify existing processes to achieve desirable metal incorporation effects or, otherwise, the drawback is that the specialty gas can only be added in extremely small amounts.

### DOCUMENTS OF RELATED ART

Japanese Patent Publication No. 2015-501538

### DISCLOSURE

### Technical Problem

The present invention has been conceived to solve the above problems, and it is an object of the present invention to provide an etching plasma processing apparatus including a consumable metal component containing refractory metal, which can substitute the specialty gas introduced for improving the quality of etching.

### Technical Solution

In one aspect, the present invention provides an etching plasma processing apparatus including a vacuum chamber, a substrate support member arranged inside the chamber, a gas supply member for injecting gas into the chamber, a consumable part arranged inside the chamber and generating a metallic byproduct containing ions or radicals of a first metal when plasma is generated inside the chamber, a first electrode for applying power to generate plasma inside the chamber, a second electrode facing the first electrode, and a power supply supplying power to the first and second electrodes.

In one embodiment, the consumable part is installed on a shower head located at an upper part of the chamber and having one or more gas outlet holes.

In one embodiment, the consumable part is installed on an edge ring located at the bottom of the chamber to surround the edge of the substrate arranged on the substrate support member.

In one embodiment, the consumable part is installed on the inner wall of the chamber.

In one embodiment, the consumable part comprising a silicon (Si) compound or mixture containing the first metal.

In one embodiment, the first metal includes one or more of niobium (Nb), molybdenum (Mo), tantalum (Ta), tungsten (W), rhenium (Re), titanium (Ti), vanadium (V), chromium (Cr), manganese (Mn), zirconium (Zr), technetium (Tc), rubidium (Rb), rhodium (Rh), hafnium (Hf), osmium (Os), and iridium (Ir).

In one embodiment, the apparatus further include a consumable part connection power supply applying power to the consumable part to facilitate the generation of ions or radicals of the first metal.

In one embodiment, the apparatus is one of a capacitively coupled plasma (CCP) apparatus, an inductively coupled plasma (ICP) apparatus, a microwave plasma apparatus, a helicon plasma apparatus, an electron cyclotron resonance (ECR) plasma apparatus, and a remote plasma apparatus.

### Advantageous Effects

According to the present invention, the etching process can be improved by using a consumable metal member containing refractory metal in the etching plasma processing apparatus, instead of a specialty gas containing a refractory metal, to achieve desirable sidewall passivation. As a consequence, it becomes to possible to carry out a more economical etching process by eliminating the need for additional gas line installations for specialty gas injection while utilizing the by-products of the consumable metal member. Furthermore, the direct deposition through sputtering without the need for direct injection of specialty gases allows for effective sidewall passivation and protection, helping overcome the limitations in fine pattern etching of the high aspect ratio contact (HARC) etching process.

### DESCRIPTION OF DRAWINGS

FIG. 1 shows a circuit diagram of an apparatus and a schematic diagram of a consumable part according to an embodiment of the present invention;

FIG. 2 shows a circuit diagram of an apparatus with a consumable part connected to one power supply and a schematic diagram of the consumable part;

FIG. 3 is a circuit diagram of an apparatus with a consumable part connected to two power supplies and a schematic diagram of the consumable part;

FIG. 4 is a diagram illustrating a configuration of a dual-frequency capacitively coupled plasma (CCP) apparatus of the present invention;

FIG. 5 is a diagram illustrating a configuration of a dual-frequency capacitively coupled plasma (CCP) apparatus of the present invention;

FIG. 6 is a diagram illustrating a configuration of an inductively coupled plasma (ICP) apparatus of the present invention;

FIG. 7 is a diagram illustrating a configuration of a microwave plasma apparatus of the present invention;

FIG. 8 is a diagram illustrating a configuration of a remote plasma apparatus of the present invention;

FIG. 9 is a diagram illustrating a configuration of using a self DC bias according to an embodiment of the present invention; and

FIG. 10 is a diagram illustrating a configuration using a self DC bias according to another embodiment of the present invention.

### BEST MODE FOR INVENTION

The most preferred embodiment according to the present invention includes a vacuum chamber, a substrate support member arranged inside the chamber, a gas supply device for injecting gas into the chamber, a consumable part located inside the chamber and generating a metallic byproduct containing ions or radicals of a first metal when plasma is generated inside the chamber, a first electrode for applying power to generate plasma inside the chamber, a second electrode facing the first electrode, and a power supply for supplying power to the first and second electrodes.

### MODE FOR INVENTION

Hereinafter, the present invention is described in detail through embodiments. The present invention is capable of being modified in various ways and taking on different forms, and preferred embodiments are illustrated in the accompanying drawings and described in detail. However, such embodiments are not intended to limit the invention and it should be understood that the embodiment include all changes, equivalents, and substitutes within the spirit and scope of the invention.

The terms “first,” “second,” etc. are used to describe various components, but the components should not be limited by these terms. The terms are used only for distinguishing one component from another component.

Throughout the specification, when any portion is said to “include” or “contain” any component, it is intended to mean that the portion may include other components, unless specifically defined otherwise. As used herein, the singular forms are intended to include the plural forms as well, unless the context clearly indicates otherwise.

Unless otherwise defined differently, all terms including technical or scientific terms used herein have the same meanings as commonly understood by those skilled in the art to which the present invention belongs and are not to be construed in an idealized or overly formal sense unless explicitly defined in this application.

Hereinafter, a description is made of the etching plasma processing apparatus disclosed in the present invention with reference to accompanying drawings.

The present invention provides an etching plasma processing apparatus including a vacuum chamber, a substrate support member arranged inside the chamber, a gas supply member for injecting gas into the chamber, a consumable part arranged inside the chamber and generating a metallic byproduct containing ions or radicals of a first metal when plasma is generated inside the chamber, a first electrode applied with power to generate plasma inside the chamber, a second electrode facing the first electrode, and a power supply supplying power to the first and second electrodes.

The etching plasma processing apparatus may be used in semiconductor etching processes, preferably high aspect ratio contact (HARC) etching processes in semiconductor fabrication. In addition, the etching plasma processing apparatus may a capacitively coupled plasma (CCP) apparatus, a inductively coupled plasma (ICP) apparatus, a microwave plasma apparatus, a helicon plasma apparatus, an electron cyclotron resonance (ECR) plasma apparatus, or a remote plasma apparatus. The etching plasma processing apparatus may include a vacuum chamber capable of maintaining internal vacuum, inject gas into the chamber, and apply power to generate plasma inside the chamber. The power may be a radio frequency (RF) power. In addition, the present invention can improve the passivation efficiency and vertical etching efficiency of the etching process by using a consumable metal member that sputters or reacts in an indirect injection manner rather than a direct injection method that directly injects the etching gas.

Hereinafter, a description is made of the etching plasma processing apparatus disclosed in the present invention with reference to accompanying drawings.

The present invention may include a vacuum chamber, a substrate support member arranged inside the chamber, a gas supply member for injecting gas into the chamber, a consumable part arranged inside the chamber and generating a metallic byproduct containing ions or radicals of a first metal when plasma is generated inside the chamber, a first electrode applied with power to generate plasma inside the chamber, a second electrode facing the first electrode, and a power supply supplying power to the first and second electrodes.

The high aspect ratio contact etching process is a process for high aspect ratio etching, including vertical etching of NAND flash with a high aspect ratio due to the high density of stacked dielectric films. The high aspect ratio contact etching process may cause problems such as bowing, twisting, loading effect, charging effect, and uneven passivation of the sidewall, as many dielectrics are stacked. Therefore, to solve these problems, it is necessary to inject a specialty gas containing metal in addition to the etching gas. However, this requires the expansion of additional equipment for injecting the specialty gas.

In the present invention, instead of injecting a specialty gas containing metals, a refractory metal, preferably a metal-containing silicon (Si) compound or mixture containing metals, and even more preferably, metal-containing silicide compounds may be included in the consumable metal member of the existing etching plasma processing apparatus. In this case, the consumable metal member may be referred to as the consumable part, which may be located inside the chamber of the etching plasma processing apparatus and preferably installed in a detachable and replaceable component within the chamber, with its surface exposed to the plasma during the etching process.

The exposed surface of the consumable part undergoes plasma etching inside the chamber, and the reaction byproducts of the consumable part, such as molybdenum (Mo), nickel (Ni), tantalum (Ta), and tungsten (W) halide compounds, may be utilized to replace the additive effects obtained by injecting conventional specialty gases containing metals (such as TaF₆, WF₆, WF₅Cl, WBr₆, W(CO)₆, WCl₆, and BiF₅). In this case, the ions or radicals of the first metal are combined with the polymer material undergoing plasma deposition and subsequently deposit on the substrate.

Here, the consumable part may be installed on a shower head located on the top of the chamber and having one or more gas outlet holes, or on an edge ring located at the bottom of the chamber so as to surround the edge of the substrate placed on the substrate support, or on the inner wall of the chamber. When the consumable part is installed on the inner wall of the chamber, it may partially replace a section of the inner wall of the chamber or exist in a form arranged on the inner wall of the chamber. The consumable part may exist in various forms and structures without being limited to the specific forms aforementioned, as long as it is located inside the chamber and the surface in a way that its surface is exposed to the plasma, allowing etching to occur.

The consumable part may include silicon (Si) compounds or mixtures containing the first metal, and the first metal may preferably include one or more refractory metals such as niobium (Nb), molybdenum (Mo), tantalum (Ta), tungsten (W), rhenium (Re), titanium (Ti), vanadium (V), chromium (Cr), manganese (Mn), zirconium (Zr), technetium (Tc), rubidium (Rb), rhodium (Rh), hafnium (Hf), osmium (Os), and iridium (Ir), more preferably one or more of niobium (Nb), molybdenum (Mo), tantalum (Ta), tungsten (W), and rhenium (Re), most preferably tungsten (W) in the form of a silicon (Si) compound or mixture containing metal.

The etching plasma processing apparatus of the present invention may further include a consumable part connection power supply that applies power to the consumable part to facilitate the generation of ions or radicals of the first metal.

When plasma is generated inside the chamber of the etching plasma processing apparatus, the surface of the consumable part exposed to the plasma may be consumed by radicals or through sputtering, leading to the generation of byproducts. In order to control the generation of byproducts, additional power may be connected to the consumable part to apply electrical power, which may be DC power, AC power, or RF power (including pulse power).

In addition, the apparatus is one of a capacitively coupled plasma (CCP) apparatus, an inductively coupled plasma (ICP) apparatus, a microwave plasma apparatus, a helicon plasma apparatus, an electron cyclotron resonance (ECR) plasma apparatus, and a remote plasma apparatus. The apparatus according to embodiments of the present invention is described hereinafter with reference to accompanying drawings.

Hereinafter, various embodiments and evaluation examples of the present invention are described in detail. However, the following embodiments are merely some embodiments of the present invention, and the present invention should not be interpreted as being limited to the following embodiments.

### Embodiment

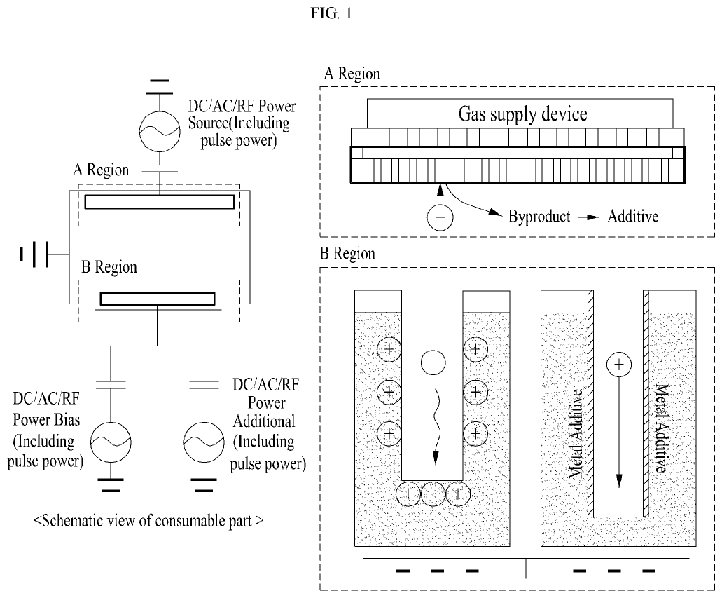

FIG. 1 shows a circuit diagram of an apparatus and a schematic diagram of a consumable part according to an embodiment of the present invention.

With reference to FIG. 1, the etching plasma processing apparatus includes an A-region containing a consumable part located at the top of the chamber and a B-region containing a substrate support, preferably an electrostatic chuck (ESC), located at the bottom of the chamber. In this case, the inclusion of a consumable part in the A-region means that the consumable part is installed on the gas supply device in the A-region, preferably the distribution gas distributed plate (DGDP) or the upper electrode. Furthermore, the apparatus includes a lower electrode supplying energy to generate plasma and an additional upper electrode facing the lower electrode and grounded. In this embodiment, the upper electrode may be a plate that sprays gas, preferably the Distribution Gas Distributed Plate (DGDP). The lower electrode and the upper electrode are connected to power supplies to supply power, and the power supplies may be DC power, AC power, or RF power (including pulse power).

The etching plasma processing apparatus may inject gas into the vacuum chamber through the gas distribution plate (DGDP) or the upper electrode in the A-region when the wafer is placed on the electrostatic chuck in the B-region. Afterward, by applying power to the lower electrode in the B-region, plasma is generated inside the chamber, and the plasma and the wafer in the B-region undergo a chemical reaction, resulting in the progression of the etching process on the wafer surface. In this case, the plasma reacts with the metal consumable part installed in the A-region of the chamber and exposed to the chamber interior, and the byproduct formed by the reaction of the metal consumable part and the plasma acts as a specialty gas additive, coating the side that should not be etched during etching in the B-region with the additive, thereby contributing to improving the quality of the high aspect ratio etching process by forming an etching process in the vertical direction.

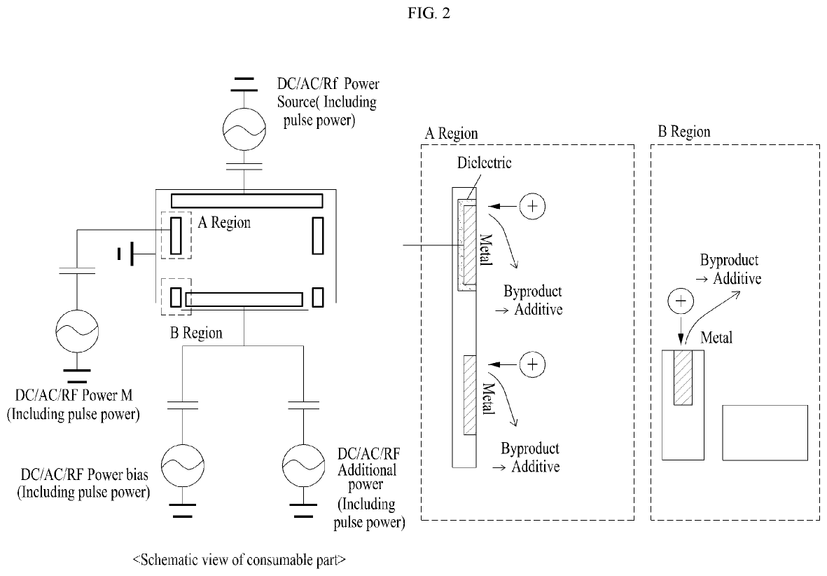

FIG. 2 shows a circuit diagram of an apparatus with a consumable part connected to one power supply and a schematic diagram of the consumable part.

FIG. 2 depicts an etching plasma processing apparatus with a consumable part installed in the B-region, which includes the edge ring around the substrate, in addition to the A-region including a sidewall of the chamber, and there is an additional power supply connected to the consumable part in the A-region in addition to the power supplies connected to the upper and lower electrodes. The power supplies may be a DC power supply, an AC power supply, or RF power supply (including pulse power supply) capable of controlling the amount of byproduct generated during the etching of the consumable part in the A-region. Furthermore, the consumable part in the A-region may exist solely in the A-region or may include a dielectric material between the sidewall and the consumable part.

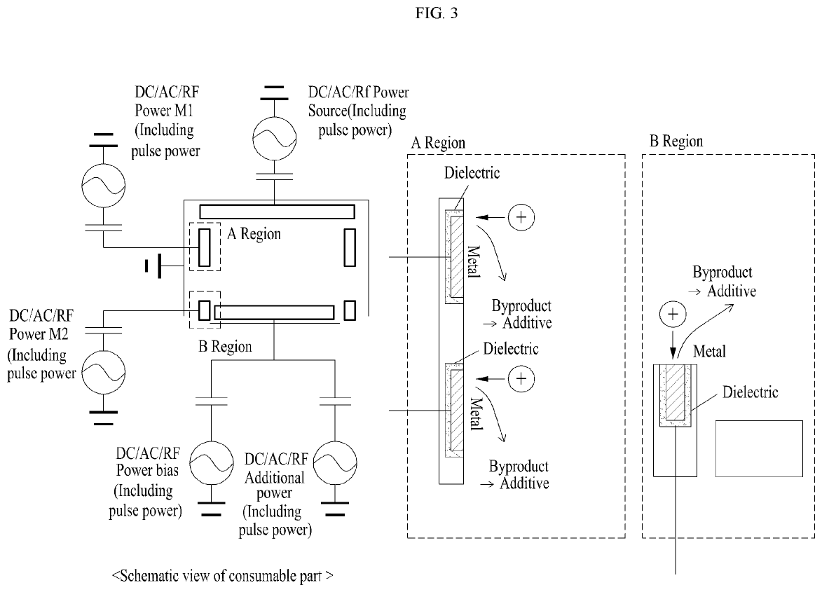

FIG. 3 shows a circuit diagram of an apparatus with a consumable part connected to one power supply and a schematic diagram of the consumable part.

FIG. 3 depicts an etching plasma processing apparatus with a consumable part installed in the B-region, which includes the edge ring around the substrate, in addition to the A-region including a sidewall of the chamber, and there are additional power supplies connected to the consumable parts in the A-region and B-region in addition to the power supplies connected to the upper and lower electrodes. The power supplies may be a DC power supply, an AC power supply, or an RF power supply (including pulse power supply) capable of controlling the amount of byproduct generated during the etching of the consumable part in the A-region. Furthermore, the consumable parts in the A-region and B-region may exist solely in the respective regions or may include dielectric material added between the sidewall and the consumable part.

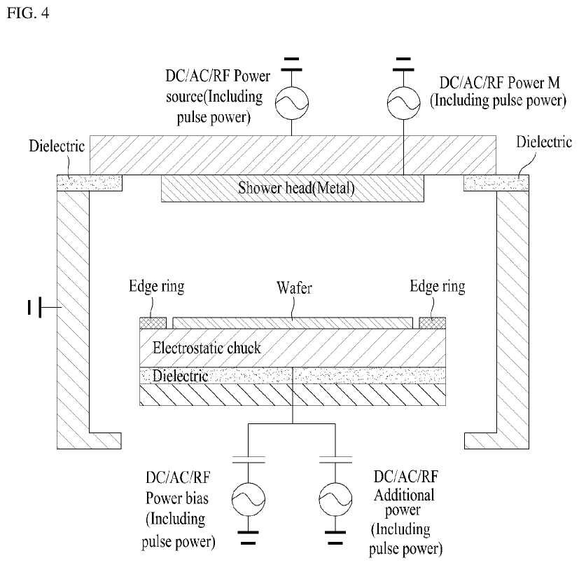

FIGS. 4 to 9 illustrate various configurations of the consumable part in different types of etching plasma processing apparatus according to the present invention. The apparatus depicted below include a plasma power supply, a bias power supply, an additional power supply, and a consumable part connection power supply.

FIG. 4 is a diagram illustrating a configuration of a dual-frequency capacitively coupled plasma (CCP) apparatus of the present invention.

With reference to FIG. 4, the shower head of the capacitively coupled plasma apparatus may include a consumable part, and the shower head may be detached and replaced. Although not shown in FIG. 4, the edge ring and sidewall of the apparatus may also include consumable parts that are detachable and replaceable. The apparatus may further include a consumable part connection power supply (Power M) to control the etching of the shower head, and the consumable part connection power supply may be connected to the shower head to supply power to the consumable part installed in the shower head. In addition to the consumable part connection power supply, the source power supply is connected to the upper electrode of the device, and the bias and additional power supplies are connected to the lower electrode. Furthermore, dielectric material may be included on the sidewall or beneath the electrostatic chuck (ESC).

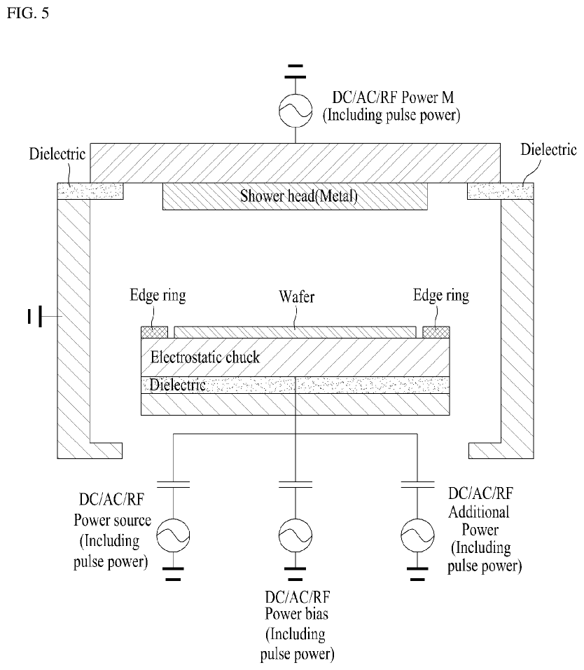

FIG. 5 is a diagram illustrating a configuration of a dual-frequency capacitively coupled plasma (CCP) apparatus of the present invention.

With reference to FIG. 5, the shower head of the capacitively coupled plasma apparatus may include a consumable part, and the shower head is detachable and replaceable. Although not shown in FIG. 5, the apparatus may also include removable and replaceable consumable parts in the edge ring and sidewall. The apparatus may further include a consumable part connection power supply (Power M) to control the etching of the shower head, and the consumable part connection power supply may be connected to the upper electrode to which the shower head is attached to supply power to the consumable part installed in the shower head. In addition to the consumable part connection power supply, the source and bias power supplies are simultaneously connected to the lower electrode of the apparatus, and an additional power supply is also connected, for a total of 3 power supplies. Furthermore, dielectric material may be included on the sidewall or beneath the electrostatic chuck (ESC).

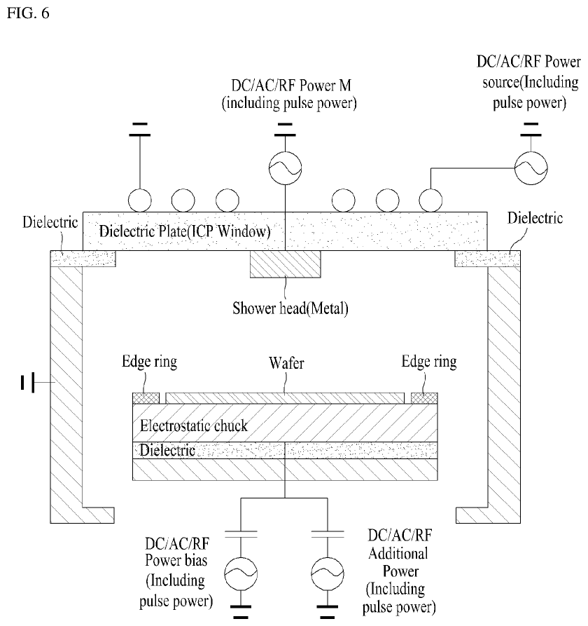

FIG. 6 is a diagram illustrating a configuration of an inductively coupled plasma (ICP) apparatus of the present invention.

With reference to FIG. 6, the shower head of the inductively coupled plasma apparatus may include a consumable part, and the shower head is detachable and replaceable. Although not shown in FIG. 6, the edge ring and sidewall of the apparatus may also include consumable parts that are detachable and replaceable. The apparatus may further include a consumable part power source (Power M) to control the etching of the shower head, and the consumable part power supply may be connected to the shower head to supply power to the consumable part installed in the shower head. In addition to the consumable part connection power supply, the source power supply is connected to the upper dielectric plate (ICP Window) of the apparatus, and the bias and additional power supplies are connected to the lower part. Furthermore, the dielectric material may be included in the lower part of the electrostatic chuck (ESC).

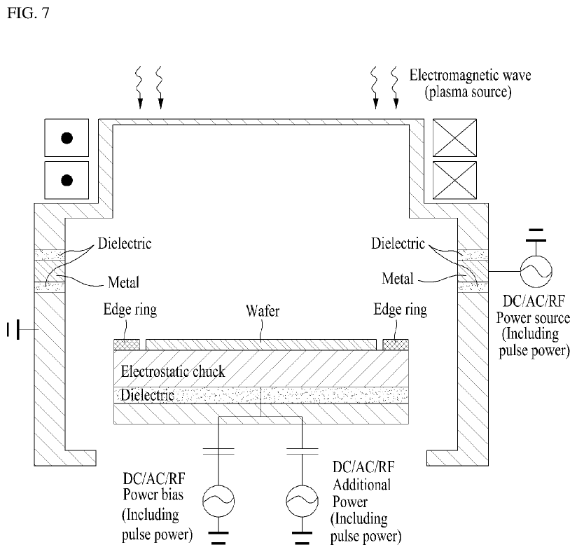

FIG. 7 is a diagram illustrating a configuration of a microwave plasma apparatus of the present invention.

With reference to FIG. 7, the sidewall of the microwave plasma apparatus may include a consumable part, and the consumable part installed on the sidewall may be detachable and replaceable. Although not shown in FIG. 7, the edge ring of the apparatus may also include a consumable part that is detachable and replaceable. The apparatus may further include a consumable part connection power supply (Power M) to control the etching of the consumable part inside the sidewall, and the consumable part connection power supply may be connected to the consumable part inside the sidewall to supply power to the consumable part inside the sidewall. In addition to the consumable part connection power supply, the bias and additional power supplies are connected to the lower part of the apparatus. The apparatus may receive the plasma source through microwave from the upper part instead of the source power supply. Additionally, dielectric material may be included on the contact surface of the consumable part and the sidewall or on the lower part of the electrostatic chuck (ESC).

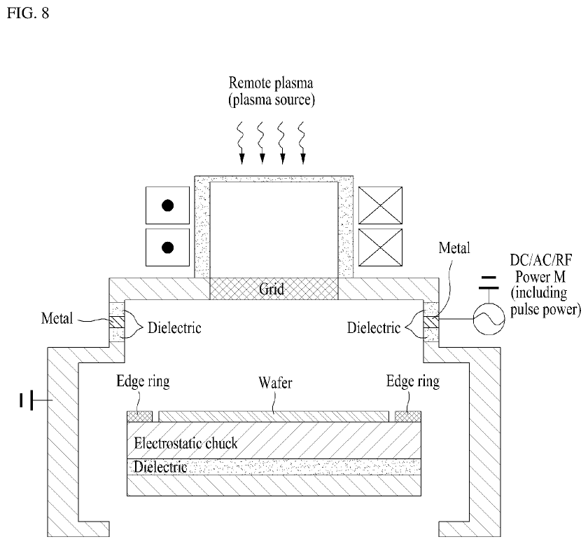

FIG. 8 is a diagram illustrating a configuration of a remote plasma apparatus of the present invention.

With reference to FIG. 8, the metal component (labeled as Metal in the drawing) located on the upper inner wall adjacent to the plasma source inlet of the remote plasma apparatus may include a consumable part, and the metal component (labeled as Metal in the drawing) is detachable and replaceable. In addition, although not shown in FIG. 8, the apparatus may include a consumable part detachable and replaceable in the grid located at the plasma source inlet, as well as in the edge ring and sidewall of the apparatus. The apparatus may further include an additional consumable part connection power supply (Power M) to control the etching of the metal part (labeled as Metal in the drawing), and the consumable part connection power supply may be connected to the metal part (labeled as Metal in the drawing) to supply power to the consumable part installed in the metal part (labeled as Metal in the drawing). The remote plasma apparatus does not include additional power supplies (source power, bias power supply, and additional power supply) other than the consumable part connection power supply within the apparatus, as it receives the plasma source from an external plasma source supply. Additionally, the apparatus may include a dielectric material covering the grid of the injection port or a dielectric material on the underside of the electrostatic chuck (ESC).

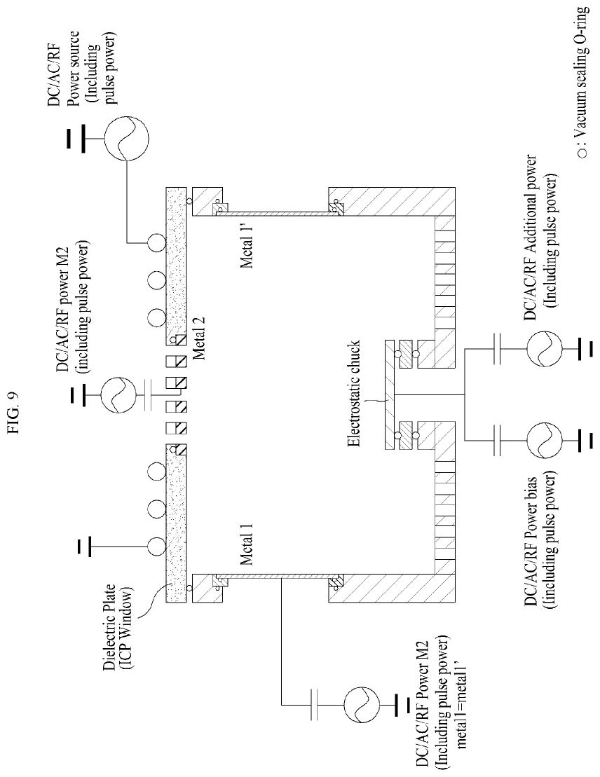

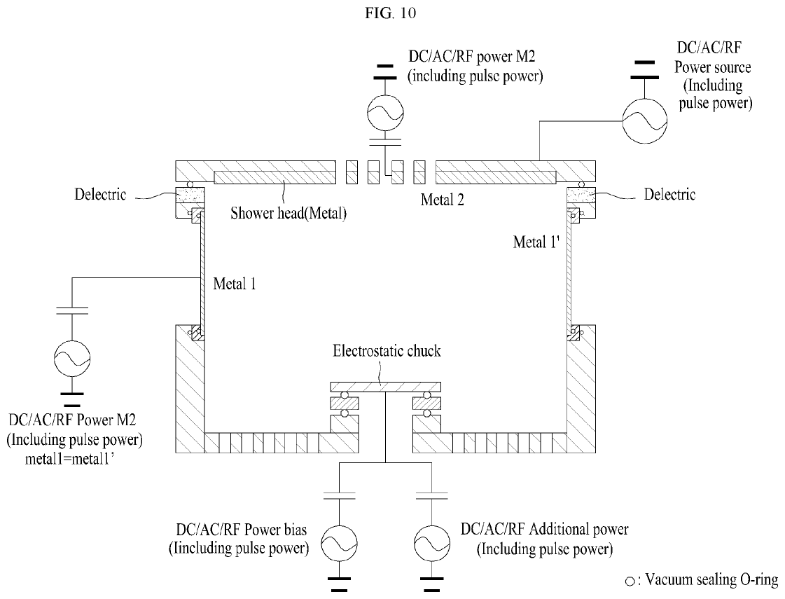

FIG. 9 is a diagram illustrating a configuration of using a self DC bias according to an embodiment of the present invention, and FIG. 10 is a diagram illustrating a configuration using a self DC bias according to another embodiment of the present invention.

With reference to FIG. 9, the apparatus includes a gas supply device at the upper part and a gas exhaust device at the lower part, and similar to the apparatuses in other embodiments, the wafer plasma etching process may be carried out on the substrate support member, preferably on the electrostatic chuck (ESC). The apparatus uses a magnetic DC bias to perform a plasma etching process, and similar to the apparatuses in other embodiments, power is applied to a consumable part exposed to the plasma in the chamber of the apparatus to control the etching amount and the amount of byproducts generated by the consumable part. In FIG. 9, the consumable part may be in the form of metal (Metal 1 and Metal 1′) connecting the upper and lower parts of the sidewall, which are separated by a vacuum sealing O-ring, and may also be in the form of a shower head attached to the upper gas supply device. To control the etching of the consumable parts of the sidewall and shower head, the apparatus may further include a consumable part connection power supply (Power M) connected to the consumable parts of the sidewall and shower head to supply power to the consumable parts. In addition to the consumable part connection power supply, the source power supply is connected to the upper dielectric plate of the apparatus, and the bias and additional power are connected to the lower part of the apparatus, preferably the electrostatic chuck (ESC). In addition, the upper gas supply device of the apparatus may be a dielectric plate (ICP Window) in its entirety.

FIG. 10 shows a configuration mostly the same as FIG. 9, but the dielectric is positioned on the sidewall instead of existing in plate form at the upper part.

With reference to FIG. 10, the apparatus includes a gas supply device at the upper part and a gas exhaust device at the lower part, and similar to the apparatuses in other embodiments, the wafer plasma etching process may be carried out on the substrate support member, preferably on the electrostatic chuck (ESC). The apparatus uses a magnetic DC bias to perform a plasma etching process, and similar to the apparatuses in other embodiments, power is applied to a consumable part exposed to the plasma in the chamber of the apparatus to control the etching amount and the amount of byproducts generated by the consumable part. In FIG. 10, the consumable part may be in the form of metal (Metal 1 and Metal 1′) connecting the upper and lower parts of the sidewall, which are separated by a vacuum sealing O-ring, and may also be in the form of a shower head attached to the upper gas supply device. The apparatus may further include a consumable part connection power supply (Power M) to control the etching of the consumable parts on the sidewall and shower head, and the consumable part connection power supply may be connected to the consumable parts on the sidewall and the shower head to supply power to the consumable parts. In addition to the consumable part connection power supply, the apparatus includes a source power supply at the upper part and bias and additional power supplies at the lower part, preferably connected to the electrostatic chuck (ESC). Furthermore, the apparatus may include dielectric material on the upper sidewall.

Although the above description has been made with reference to the preferred embodiments of the present invention, it should be understood by those skilled in the art that various modifications and alterations can be made to the present invention without departing from the spirit and scope of the present invention as set forth in the claims below.

1. An etching plasma processing apparatus comprising:
a vacuum chamber;
a substrate support member arranged inside the chamber;
a gas supply member for injecting gas into the chamber;
a consumable part arranged inside the chamber and generating a metallic byproduct containing ions or radicals of a first metal when plasma is generated inside the chamber;
a first electrode for applying power to generate plasma inside the chamber;
a second electrode facing the first electrode; and
a power supply supplying power to the first and second electrodes.

2. The etching plasma processing apparatus of claim 1, wherein the ions or radicals of the first metal combine with a polymer material plasma-deposited on the substrate and deposited on the substrate.

3. The etching plasma processing apparatus of claim 1, wherein the consumable part is installed on a shower head located at an upper part of the chamber and having one or more gas outlet holes.

4. The etching plasma processing apparatus of claim 1, wherein the consumable part is installed on an edge ring located at the bottom of the chamber to surround the edge of the substrate arranged on the substrate support member.

5. The etching plasma processing apparatus of claim 1, wherein the consumable part is installed on the inner wall of the chamber.

6. The etching plasma processing apparatus of claim 1, wherein the consumable part comprising a silicon (Si) compound or mixture containing the first metal.

7. The etching plasma processing apparatus of claim 1, wherein the first metal comprises one or more of niobium (Nb), molybdenum (Mo), tantalum (Ta), tungsten (W), rhenium (Re), titanium (Ti), vanadium (V), chromium (Cr), manganese (Mn), zirconium (Zr), technetium (Tc), rubidium (Rb), rhodium (Rh), hafnium (Hf), osmium (Os), and iridium (Ir).

8. The etching plasma processing apparatus of claim 1, further comprising a consumable part connection power supply applying power to the consumable part to facilitate the generation of ions or radicals of the first metal.

9. The etching plasma processing apparatus of claim 1, is one of a capacitively coupled plasma (CCP) apparatus, an inductively coupled plasma (ICP) apparatus, a microwave plasma apparatus, a helicon plasma apparatus, an electron cyclotron resonance (ECR) plasma apparatus, and a remote plasma apparatus.
